(19) United States
(12) Patent Application Publication
(10) Pub. No.: US 2024/0282870 A1
(43) Pub. Date: Aug. 22, 2024

(54) METHOD FOR IMPROVING THE OHMIC CONTACT BETWEEN A FRONT CONTACT GRID AND A DOPED LAYER OF A WAFER SOLAR CELL

(71) Applicant: HANWHA Q CELLS GMBH, Bitterfeld-Wolfen (DE)

(72) Inventors: Florian STENZEL, Bitterfeld-Wolfen (DE); Ansgar METTE, Bitterfeld-Wolfen (DE); Stefan HOERNLEIN, Bitterfeld-Wolfen (DE); Martin SCHAPER, Bitterfeld-Wolfen (DE); Axel SCHWABEDISSEN, Bitterfeld-Wolfen (DE); Janko CIESLAK, Bitterfeld-Wolfen (DE); Eckehard HOFMUELLER, Kabelsketal (DE); Stefan STOECKEL, Kabelsketal (DE); Eve KRASSOWSKI, Kabelsketal (DE)

(21) Appl. No.: 18/581,984

(22) Filed: Feb. 20, 2024

(30) Foreign Application Priority Data
Feb. 20, 2023 (DE) 102023104164.9

(51) Int. Cl. H01L 31/0224; H01L 31/0687

(52) U.S. Cl. CPC H01L 31/022458; H01L 31/022433; H01L 31/0687

(57) ABSTRACT

A method for improving the ohmic contact between a front contact grid and a doped layer of a wafer solar cell, including: providing the wafer solar cell; electrically contacting the front contact grid with a contacting device electrically connected to a pole of a voltage source; electrically contacting another contacting device electrically connected to the other pole of the voltage source with a back contact grid of the cell; applying a voltage directed against the forward direction of the cell to the front contact grid and the back contact grid with the voltage source, wherein the voltage is smaller than a breakdown voltage of cell; guiding a point light source over the sun-averted back side of the cell while the voltage is applied, wherein a partial region of the sun-averted back side is illuminated such that a current flow is induced in, and acts on, the partial region.

### PRIORITY CLAIM

The present application claims priority to German Patent Application No. 102023104164.9, filed on Feb. 20, 2023, which said application is incorporated by reference in its entirety herein.

### FIELD OF THE INVENTION

The invention relates to a method for improving the ohmic contact between a front contact grid and a doped layer of a wafer solar cell.

### BACKGROUND OF THE INVENTION

Depending on the process control during the production of the wafer solar cell with the emitter layer in the form of a doped layer and the front contact grid, there may be high contact resistances in places at the junction between a metal paste provided for producing the front contact grid and the doped layer. Such excessively high contact resistances as a rule lead to a reduced efficiency for the wafer solar cell.

DE 10 2016 009 560 A1 and DE 10 2018 001057 A1 disclose methods for improving the ohmic contact between the front contact grid and the doped layer in the form of an emitter layer. In this case, a silicon wafer solar cell comprising the doped layer provided for the function as an emitter, a front contact grid, and a back contact is initially provided. Then the front contact grid is electrically connected to a pole of a voltage source and a contacting device electrically connected to the other pole of the voltage source is connected to the back contact. The voltage source is used to apply a voltage directed against the forward direction of the silicon wafer solar cell, which voltage is smaller in magnitude than the breakdown voltage of the silicon wafer solar cell. When the voltage is applied, a point light source is guided over the sun-facing side of the silicon wafer solar cell. A section of a partial region of the sun-facing side is illuminated in the process, and a current flow is thus locally induced in the partial region. This current flow related to the section has a current density from 200 A/cm² to 20,000 A/cm² and acts on the partial region for 10 ns to 10 ms.

However, as the current flows to the solar cell contacts, some of the electrical voltage drops due to resistance. A contact point near the contacting device thus experiences other effective process parameters than a contact point further away from the contacting device. The applied reverse voltage, which has a significant influence on the quality of this process, is thus distributed inhomogeneously over the wafer solar cell. As a result of the method, this leads to a wafer solar cell with reduced efficiency.

### SUMMARY OF THE INVENTION

It is an object of the invention to provide a method for improving the ohmic contact between a front contact grid and a doped layer of a wafer solar cell by means of which the wafer solar cell with improved efficiency is provided.

According to the invention, the object is achieved by a method having the features of the claims. Advantageous developments and modifications are specified in the claims.

The invention relates to a method for improving the ohmic contact between a front contact grid and a doped layer of a wafer solar cell, the method comprising the following steps:
providing the wafer solar cell having the doped layer, the front contact grid, and a back contact grid,
electrically contacting the front contact grid with a contacting device electrically connected to a pole of a voltage source,
electrically contacting a further contacting device electrically connected to the other pole of the voltage source with the back contact grid,
applying a voltage directed against the forward direction of the wafer solar cell to the front contact grid and the back contact grid by means of the voltage source, wherein the applied voltage is smaller in magnitude than the breakdown voltage of the wafer solar cell,
guiding a point light source over the sun-averted back side of the wafer solar cell while the voltage is applied, wherein a section of a partial region of the sun-averted back side is illuminated such that a current flow is induced in the partial region and acts on the partial region.

In contrast to the methods described in DE 10 2016 009 560 and DE 10 2018 001057 A1, the point light source is not guided over the sun-facing front side of the wafer solar cell, but over the sun-averted back side of the wafer solar cell. It has been found that this brings about a surprisingly effective improvement of the ohmic contact between the front contact grid and the doped layer, thereby providing a wafer solar cell with improved efficiency.

In a preferred embodiment, the front contact grid and the back contact grid respectively cover the front side and back side of the wafer solar cell with a degree of metallization, with the back contact grid having a greater degree of metallization in terms of area than the front contact grid. The degree of metallization refers to the region in terms of the area covered by the conductor surface in relation to regions that remain free. This applies to the respective side, i.e. the sun-facing front side or the sun-averted back side. The greater the degree of metallization of the conductor surface, the lower the current generated in a solar cell. The sun-facing front side, which normally generates about 90% of the cell's power, typically contains less conductive surface in the form of contact fingers and busbars than the sun-averted back side in order to minimize shading on the main power generation side of the wafer solar cell. Therefore, the conduction path of the reverse current to the light spot of the point light source is usually longer and varies more than on the sun-averted back side having a greater degree of metallization. The lower degree of metallization of the sun-facing front side leads to higher resistances and thus to higher voltage losses in the light spot generated by the point light source while the reverse voltage is applied. An electrical resistance of a current generated by a light spot near the electrical contact is comparatively low and leads to a correspondingly low voltage loss. However, the resistance of a current generated by a light spot that is farther away from the electrical contact is significantly higher and results in a significant voltage loss. Therefore, an inhomogeneous result for this method arises when the sun-facing front side with the lower degree of metallization is illuminated. When the sun-averted back side is illuminated while the voltage is applied, the greater degree of metallization leads to lower resistances and thus to lower voltage losses for the reasons described above. The electrical resistance of an electric current generated by a light spot near the electrical contact is very low and leads to a very low voltage loss. The electrical resistance of an electric current generated by a light spot or two-dimensional illumination further away from the electrical contact is slightly greater and correspondingly leads to a slightly greater voltage loss. As a result, the method yields a more homogeneous result when the sun-averted back side is illuminated and a higher efficiency for the wafer solar cell.

Preferably, the front contact grid and the back contact grid each have an electrical conductivity, wherein the back contact grid has a higher electrical conductivity than the front contact grid. The advantages correspond to the advantages mentioned above for the degree of metallization.

In a preferred embodiment, the front contact grid and the back contact grid respectively have a layer resistance in the material on the front side and back side, wherein the back contact grid has a lower layer resistance in the material on the back side than the front contact grid on the front side. The advantages correspond to the advantages mentioned above for the degree of metallization.

Preferably, the back contact grid has a greater degree of metallization, a higher conductivity than the front contact grid and a lower layer resistance in the material on the back side than the front contact grid on the front side.

Preferably, the front contact grid has a multiplicity of front contact fingers arranged parallel to one another and at least one front busbar arranged transversely to the multiplicity of front contact fingers. Alternatively or additionally preferably, the back contact grid has a multiplicity of back contact fingers arranged parallel to one another and at least one back busbar arranged transversely to the multiplicity of back contact fingers. Preferably, the front busbar is arranged perpendicular to the multiplicity of front contact fingers. Preferably, the back busbar is arranged perpendicular to the multiplicity of back contact fingers.

In a preferred embodiment, the front contact fingers are arranged at a distance from one another which is greater than a further distance at which the back contact fingers are arranged from one another. Thus, a degree of metallization of the sun-averted back side can be provided which is greater than the degree of metallization of the sun-facing front side.

Preferably, a number of back contact fingers is greater than a number of front contact fingers. This is a further way to provide a degree of metallization of the sun-averted back side that is greater than the degree of metallization of the sun-facing front side.

In a preferred embodiment, the wafer solar cell is textured on the front side and the back side of the wafer solar cell is smoothed out with a mean surface roughness <2 μm. The term “textured” should be understood to mean that the surface has an average surface roughness of >2 μm. While pyramid-like structures are preferably formed at the front surface, the back side is preferably smoothed out in such a way that its surface has only truncated pyramids. Texturing reduces the penetration/illumination effectiveness of the light beam or light spot produced by the point light source. Therefore, it is more effective to illuminate the wafer solar cell from the sun-averted back side while the voltage is applied. The incoming light is coupled in with less reflection due to the texture, but is also very strongly scattered. This is an advantage when operating the wafer solar cell. In the method, however, the generated current flows over a larger area during illumination and while the voltage is applied.

As a result, the effective range is larger and the electrical contact properties are partially influenced by a plurality of contact fingers simultaneously. Therefore, the method cannot be controlled as well as for the smoothed back side during the illumination of the textured front side while the voltage is applied.

Preferably, the front side of the wafer solar cell has a greater surface roughness than the back side of the wafer solar cell. The difference in surface roughness will be caused as a rule by the front-side texturing. During the illumination of the back side having a lower surface roughness, the low roughness causes a larger portion of the incident light to be reflected compared with the front side, but it is less scattered in the wafer solar cell. The resulting current therefore flows over a smaller area. The effective range is therefore smaller. Therefore, the method can be controlled more precisely in this way.

The method is preferably carried out with the following parameters:

Preferably, a voltage, which is in the range from 1 to 40 V, is applied by means of the voltage source to the front contact grid and the back contact grid in the opposite direction of the forward direction. Preferably, the local illumination has a power density in the range from 200 to 500,000 W/cm². The method is preferably carried out so that a current from 0.1 to 10 A flows between the front and back contacts.

The wafer solar cell provided in the method preferably has the following parameters:

Preferably, the wafer solar cell provided has a contact resistance of >50 mOhm/cm², measured with the TLM method (transfer length method) before the method according to the invention is carried out. In a preferred embodiment, the wafer solar cell provided has a contact area of less than 0.1% prior to carrying out the method according to the invention. This means that the metallized area of the metal semiconductor contacts is less than 0.1% of the surface on which the metal semiconductor contacts are located. Preferably, the wafer solar cell provided has one or more passivation and/or anti-reflection layers. Preferably, the anti-reflection layer has a thickness of more than 100 nm. The anti-reflection layer is formed, for example, from SiNₓ (silicon nitride). The anti-reflection layer can also be formed as a SiNₓ(silicon nitride)/SiOₓN_{y} (silicon oxynitride) double layer or SiNₓ(silicon nitride)/SiOₓN_{y} (silicon oxynitride)/SiO₂ (silicon dioxide) triple layer with thicknesses greater than 100 or greater than 110 nm. Preferably, the wafer solar cell provided has a higher layer resistance of the doped layer on the front side than on the back side.

Preferably, the wafer solar cell is a bifacial solar cell.

A bifacial solar cell has the ability to use both light that is incident on the sun-facing front surface as well as light that is incident on the sun-averted back surface to generate electricity. A monofacial solar cell, on the other hand, can use only light that is incident on the sun-facing front side to generate electricity. In addition, the bifacial solar cell allows for back-side illumination due to its back side which is not completely metallized.

Alternatively, the wafer solar cell is designed as a subcell of a multi-junction solar cell. The multi-junction solar cell has at least two subcells. These subcells each have a specific p/n junction. The subcells are made of different, layered materials.

The multi-junction solar cell therefore comprises an upper, light-facing upper subcell, a lower subcell and optionally one or more middle subcell(s) arranged between the upper and lower subcells. Preferably, the wafer solar cell provided in the method according to the invention is the lower subcell of the multi-junction solar cell, which is then provided with an upper subcell and optionally middle subcell(s) after the method according to the invention has been carried out. The multi-junction solar cell can be a mechanically stacked multi-junction solar cell, in which the subcells have been produced separately from one another and then interconnected, or a monolithic multi-junction solar cell, in which all subcells have been built up on the same substrate with their layer structure for example by diffusion or by layer deposition. The multi-junction solar cell is moreover provided with at least one contact each for its front side and its back side.

The multi-junction solar cell may, for example, have a silicon solar cell as the lower subcell, which is subjected to the method according to the invention. The lower subcell is e.g.: a p-type PERC (passivated emitter and rear cell) subcell, heterojunction subcell, an n-type TOPCon (tunnel oxide passivated contact) subcell or an IBC (interdigitated back contact) subcell. The front and/or back contact grid can be optically transparent, wherein it is preferably made of TCO (transparent conductive oxides) such as ITO (indium-tin-oxide). The front and/or back contact grid may also be made of metal, e.g.: silver, however. The upper subcell can be designed as a perovskite subcell, for example.

In a preferred embodiment, the point light source is guided directly next to the back contact fingers of the back contact grid over the sun-averted back side of the wafer solar cell. This furthermore means that a wafer solar cell with improved efficiency can be produced. The feature “direct” refers to a distance of less than two, preferably less than one millimeter.

The point light source can be, for example, a laser, a light-emitting diode or focused radiation from a flash lamp. The point light source preferably emits radiation having wavelengths in the range from 400 nm to 1500 nm. Preferably, the point light source is a laser. The beam of a laser or laser diode can be shaped, focused and directed well.

### BRIEF DESCRIPTION OF THE FIGURES

Further advantages and properties of the method are explained using preferred exemplary embodiments, which are described below. The figures are not drawn to scale, but rather should be understood to be purely schematic and illustrative.

They show, schematically and not to scale:

FIG. 1 a top view of a front side of a wafer solar cell, which is subjected to a method according to the state-of-the-art;

FIG. 2 a top view of a back side of the wafer solar cell shown in FIG. 1, which is subjected to a method according to the invention;

FIG. 3 a cross-sectional view of the wafer solar cell shown in FIG. 1;

FIG. 4 a cross-sectional view of the wafer solar cell shown in FIG. 2;

FIG. 5 a partial cross-sectional view of the wafer solar cell shown in FIGS. 3 and 4, respectively.

### DETAILED DESCRIPTION

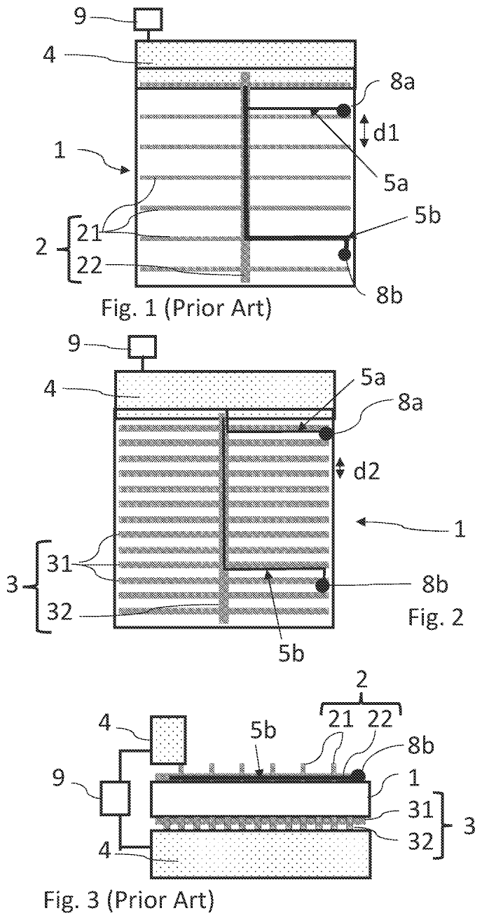

FIG. 1 shows a top view of a front side of a wafer solar cell, which is subjected to a method according to the state-of-the-art. The wafer solar cell 1 has a front contact grid 2 of a multiplicity of front contact fingers 21 arranged parallel to one another and at least one front busbar 22 arranged transversely, in particular perpendicularly, to the multiplicity of front contact fingers 21. The front contact fingers 21 are arranged at a distance d1 from one another.

The wafer solar cell 1 shown in FIG. 1 is subjected to a method for improving the ohmic contact between a front contact grid 2 and a doped layer (not shown) of the wafer solar cell 1. The method includes the following steps
providing the wafer solar cell 1 having the doped layer, the front contact grid 2, and a back contact grid (not shown in FIG. 1),
electrically contacting the front contact grid 2 with a contacting device 4 electrically connected to a pole of a voltage source 9,
electrically contacting a further contacting device (not shown in FIG. 1) electrically connected to the other pole of the voltage source 9 with the back contact grid,
applying a voltage directed against the forward direction of the wafer solar cell 1 to the front contact grid 2 and the back contact grid by means of the voltage source 9, wherein the applied voltage is smaller in magnitude than the breakdown voltage of the wafer solar cell 1,
guiding a point light source (not shown in FIG. 1) over the sun-facing front side of the wafer solar cell 1 while the voltage is applied, wherein a section of a partial region of the sun-facing front side is illuminated such that a current flow is induced in the partial region and acts on the partial region.

Two light spots 8a,8b generated by means of the point light source are shown purely by way of example. An electrical resistance 5a for the current flow generated by light spot 8a near the contacting device 4 is relatively low and thus leads to a relatively low voltage loss. However, the electrical resistance 5b for the current generated by light spot 8b further away from the contacting device 4 is significantly higher, as indicated by the thickness of the line, and inevitably leads to a high voltage loss.

FIG. 2 shows a top view of a back side of the wafer solar cell shown in FIG. 1, which is subjected to a method according to the invention. The top view shown in FIG. 2 corresponds to the top view shown in FIG. 1 with the difference that it has a back contact grid 3 of a multiplicity of back contact fingers 31 arranged parallel to one another and at least one back busbar 32 arranged transversely, in particular perpendicularly, to the multiplicity of back contact fingers 31. The back contact fingers 31 are arranged at a distance d2 from one another which is significantly smaller than the distance d1 shown in FIG. 1. In addition, the number of the back contact fingers 31 is greater than the number of the front contact fingers shown in FIG. 1. The degree of metallization of the back contact grid 3 is therefore greater than the degree of metallization of the front contact grid shown in FIG. 1.

With the wafer solar cell 1 shown in FIG. 2, a method for improving the ohmic contact between a front contact grid 2 and a doped layer (not shown in FIG. 2) of the wafer solar cell 1 is carried out. The method includes the following steps:
providing the wafer solar cell 1 having the doped layer, the front contact grid (not shown in FIG. 2), and a back contact grid 3,
electrically contacting the front contact grid with a contacting device (not shown in FIG. 2) electrically connected to a pole of a voltage source 9,
electrically contacting a further contacting device 4 electrically connected to the other pole of the voltage source 9 with the back contact grid 3,
applying a voltage directed against the forward direction of the wafer solar cell 1 to the front contact grid and the back contact grid 3 by means of the voltage source 9, wherein the applied voltage is smaller in magnitude than the breakdown voltage of the wafer solar cell 1,
guiding a point light source (not shown) over the sun-averted back side of the wafer solar cell 1 while the voltage is applied, wherein a section of a partial region of the sun-averted back side is illuminated such that a current flow is induced in the partial region and acts on the partial region.

In FIG. 2, two light spots 8a,8b generated by means of the point light source are also shown purely by way of example. When the sun-averted back side is illuminated while the voltage is applied, the greater degree of metallization here leads to lower electrical resistances 5a, 5b of the induced current and thus to lower voltage losses. The resistance 5a for a light spot 8a near the contact is very small and therefore leads to a very low voltage loss. The resistance 5b for the light spot 8b, which is slightly further away from the contact, is low and results in a correspondingly low voltage loss. The difference between the electrical resistances is smaller compared with the front side, and the method thus yields a more homogeneous result when the sun-averted back side is illuminated.

FIG. 3 shows a cross-sectional view of the wafer solar cell shown in FIG. 1. As explained in FIGS. 1 and 2, the wafer solar cell 1 comprises the front contact grid 2 with the front contact fingers 21 and the front bus bar 22 and the back contact grid 3 with the back contact fingers 31 and the back busbar 32.

The contacting device 4 electrically contacts the front contact grid 2, while the further contacting device 4 electrically contacts the back contact grid 3, wherein the contacting device electrically contacts the back side across an area in FIG. 3. The point light source (not shown) is guided over the sun-facing front side of the wafer solar cell 1 while the voltage is applied. The resistance 5b for the current induced by the light spot 8b is comparatively high, as indicated by the thickness of the line.

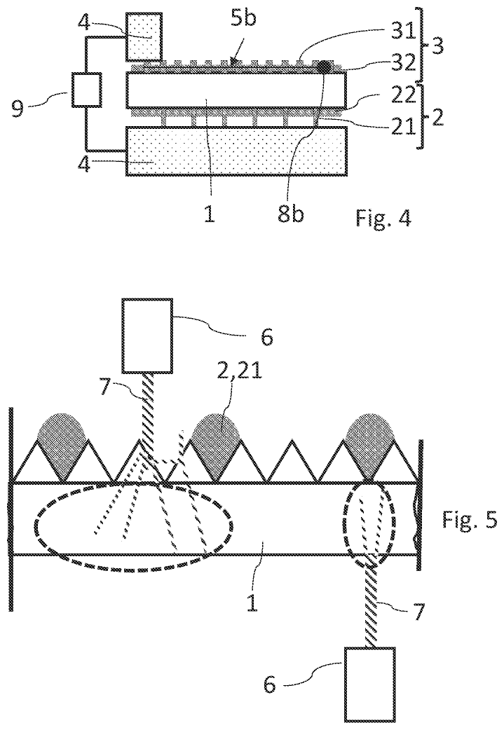

FIG. 4 shows a cross-sectional view of the wafer solar cell shown in FIG. 2. The wafer solar cell shown in FIG. 4 corresponds to the cross-sectional view shown in FIG. 3 with the difference that the contacting device 4 electrically contacts the back contact grid 3, while the further contacting device 4 electrically contacts the front contact grid 2, wherein the contacting device electrically contacts the front side across an area in FIG. 4. The point light source (not shown) is guided over the sun-averted back side of the wafer solar cell 1 while the voltage is applied. The resistance 5b for the current generated by the light spot 8b is significantly lower compared with the front illumination, as is illustrated by the thickness of the horizontal line.

FIG. 5 shows a partial cross-sectional view of the wafer solar cell shown in FIGS. 3 and 4, respectively. The back contact grid 3 is omitted for clarity, and of the front contact grid 2 the front contact fingers 21 are shown. The front surface is relatively rough due to texturing, while the back surface is smoothed out and thus less rough in comparison. FIG. 5 shows that a point light source 6 illuminates the front side of the wafer solar cell 1 with a light beam 7, and a further point light source 6 illuminates the back side of the wafer solar cell 1 with a further light beam 7, with the resulting effects being shown. Although the incident light beam 7 is coupled into the semiconductor material with less reflection losses due to the texture, it is also more spatially scattered there. However, when the front side of the wafer solar cell 1 is illuminated with the point light source 6 and the voltage is applied, the induced current flows through a larger solid angle. Thus, its effective range is more distributed and a plurality of contact fingers 21 are processed in part at the same time, but the induced current is thus also distributed to a plurality of contact fingers 21. This reduces the current per contact finger 21. Therefore, the method cannot be controlled as well during the illumination of the textured front side while the voltage is applied. During the illumination of the back side of the wafer solar cell 1 and while the voltage is applied, a greater portion of the light is reflected at the interface due to the lower roughness of the back side, but is subsequently scattered less inside the semiconductor material of the wafer solar cell. The induced current flows through a smaller solid angle. The effective range is thus more focused. Therefore, this method can be better controlled and yields a more homogeneous result.

### LIST OF REFERENCE SIGNS

d1 Distance
d2 Further distance
1 Wafer solar cell
2 Front contact grid
21 Front contact finger
22 Front busbar
3 Back contact grid
31 Back contact finger
32 Back busbar
4 Contacting device
5a,5b Resistance
6 Point light source
7 Light beam
8a,8b Light spot
9 Voltage source

1. A method for improving the ohmic contact between a front contact grid and a doped layer of a wafer solar cell, the method comprising the following steps:
providing the wafer solar cell having the doped layer, the front contact grid, and a back contact grid,
electrically contacting the front contact grid with a contacting device electrically connected to a pole of a voltage source,
electrically contacting a further contacting device electrically connected to the other pole of the voltage source with the back contact grid,
applying a voltage directed against the forward direction of the wafer solar cell to the front contact grid and the back contact grid using the voltage source, wherein the applied voltage is smaller in magnitude than a breakdown voltage of the wafer solar cell,
guiding a point light source over the sun-averted back side of the wafer solar cell while the voltage is applied, wherein a section of a partial region of the sun-averted back side is illuminated such that a current flow is induced in the partial region and acts on the partial region.

2. The method as claimed in claim 1, wherein the front contact grid and the back contact grid respectively cover a front side and back side of the wafer solar cell with a degree of metallization, have electrical conductivity, and have an electrical layer resistance in the material on the front side and back side, wherein the back contact grid has a greater degree of metallization than the front contact grid, has a higher electrical conductivity than the front contact grid, and/or has a lower electrical layer resistance in the material on the back side than the front contact grid on the front side.

3. The method as claimed in claim 1, wherein the front contact grid has a multiplicity of front contact fingers arranged parallel to one another and at least one front busbar arranged transversely to the multiplicity of front contact fingers, and/or the back contact grid has a multiplicity of back contact fingers arranged parallel to one another and at least one back busbar arranged transversely to the multiplicity of back contact fingers.

4. The method as claimed in claim 3, wherein the front contact fingers are arranged at a distance from one another which is greater than a further distance at which the back contact fingers are arranged from one another.

5. The method as claimed in claim 3, wherein a number of the back contact fingers is greater than a number of front contact fingers.

6. The method as claimed in claim 1, wherein a front side of the wafer solar cell has a greater surface roughness than a back side of the wafer solar cell.

7. The method as claimed in claim 1, wherein a voltage, which is in a range from 1 to 40 V, is applied by the voltage source to the front contact grid and the back contact grid in an opposite direction of the forward direction, wherein a local illumination has a power density in a range from 200 to 500,000 W/cm², and/or wherein a current from 0.1 to 10 A flows between the front and back contacts while the voltage is applied and during illumination.

8. The method as claimed in claim 1, wherein the wafer solar cell is a bifacial solar cell or is designed as a subcell of a multi-junction solar cell.

9. The method as claimed in claim 1, wherein the point light source is guided directly next to back contact fingers of the back contact grid over the sun-averted back side of the wafer solar cell.

10. The method as claimed in claim 1, wherein the point light source is a laser.
